(19) United States
(12) Patent Application Publication
(10) Pub. No.: US 2014/0374693 A1
(43) Pub. Date: Dec. 25, 2014

(54) VARIED MULTILAYER MEMRISTIVE DEVICE

(71) Applicant: Hans S. Cho, Palo Alto, CA (US)

(72) Inventor: Hans S. Cho, Palo Alto, CA (US)

(21) Appl. No.: 14/373,478

(22) PCT Filed: Mar. 16, 2012
(86) PCT No.: PCT/US2012/029512

§ 371 Date: Jul. 21, 2014

(51) Int. Cl. H01L 27/24; H01L 45/00

(52) U.S. Cl. CPC H01L 27/2481; H01L 45/1608; H01L 45/146; H01L 45/08; H01L 45/128
USPC 257/5; 438/382

(57) ABSTRACT

A varied multilayer memristive device includes a first memristive device stacked on a second memristive device. The physical parameters of the second memristive device differ from physical parameters of the first memristive to account for thermal budgeting differences present during formation processes for the memristive devices to reach specified performance parameters.

### BACKGROUND

A memristive device is a non-linear passive electronic component that maintains a resistance value based on previously applied electrical conditions such as currents or voltages. Such devices may be used for a variety of purposes including memory elements. Specifically, the resistive state of a memristive device may be used to represent and store digital values.

When used for memory purposes, memristive devices may be formed into memory arrays. In some cases, these arrays may be stacked to increase the volume of memory storage within a smaller amount of physical space. During the manufacturing of such arrays, the memristive formation process is affected by a thermal budget. The thermal budget is different for each layer during the formation process. Other fabrication processes such as etching may also affect each layer differently. Thus, different layers may exhibit different performance characteristics.

### BRIEF DESCRIPTION OF THE DRAWINGS

The accompanying drawings illustrate various examples of the principles described herein and are a part of the specification. The drawings are merely examples and do not limit the scope of the claims.

FIG. 1 is a diagram showing illustrative crossbar memory architecture, according to one example of principles described herein.

FIGS. 2A and 2B are diagrams showing an illustrative memristive device in different states, according to one example of principles described herein.

FIG. 3 is a diagram showing an illustrative varied multilayered memristive device, according to one example of principles described herein.

FIG. 4 is a diagram showing an illustrative varied multilayered memristive device array, according to one example of principles described herein.

FIG. 5 is a flowchart showing an illustrative method for forming a varied multilayered memristive device, according to one example of principles described herein.

Throughout the drawings, identical reference numbers designate similar, but not necessarily identical, elements.

### DETAILED DESCRIPTION

As mentioned above, when used for memory purposes, memristive devices may be formed into memory arrays. In some cases, these arrays may be stacked to increase the volume of memory storage within a smaller amount of physical space. During the manufacturing of such arrays, the memristive formation process is affected by a thermal budget. The thermal budget is different for each layer during the formation process. Thus, different layers may exhibit different performance characteristics.

In light of this and other issues, the present specification discloses methods and systems for varying the physical parameters of memristive layers to account for thermal budgeting. Specifically, the physical parameters may be varied so that memristive devices on different layers still exhibit similar performance characteristics. Alternatively, there may be cases when it is desired to have specific performance differences between different layers. These specific differences can be achieved by varying the physical parameters of each of the layers while taking into account the thermal budget.

In the following description, for purposes of explanation, numerous specific details are set forth in order to provide a thorough understanding of the present systems and methods. It will be apparent, however, to one skilled in the art that the present apparatus, systems and methods may be practiced without these specific details. Reference in the specification to “an example” or similar language means that a particular feature, structure, or characteristic described in connection with that example is included as described, but may not be included in other examples.

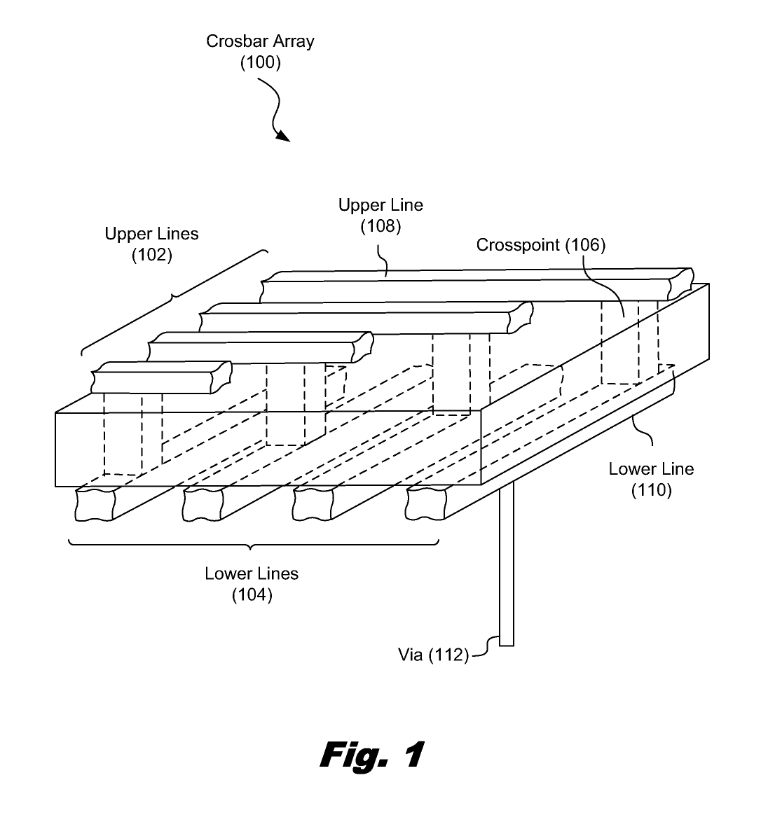

Referring now to the figures, FIG. 1 is a diagram showing illustrative crossbar memory architecture (100). According to certain illustrative examples, the crossbar architecture (100) may include an upper set of lines (102) which may generally be in parallel. Additionally, a lower set of lines (104) may be generally perpendicular to and intersect the upper lines (102). Programmable crosspoint devices (106) may be formed at the intersection between an upper line (108) and a lower line (110).

According to certain illustrative examples, the programmable crosspoint devices (106) may be memristive devices. Memristive devices exhibit a “memory” of past electrical conditions. For example, a memristive device may include a matrix material which contains mobile dopants. These dopants can be moved within a matrix to dynamically alter the electrical operation of an electrical device. The motion of dopants can be induced by the application of a programming condition such as an applied electrical voltage across a suitable matrix. The programming voltage generates a relatively high electrical field through the memristive matrix and alters the distribution of dopants. After removal of the electrical field, the location and characteristics of the dopants remain stable until the application of another programming electrical field. For example, by changing the dopant configurations within a memristive matrix, the electrical resistance of the device may be altered. The memristive device is read by applying a lower reading voltage which allows the internal electrical resistance of the memristive device to be sensed but does not generate a high enough electrical field to cause significant dopant motion. Consequently, the state of the memristive device may remain stable over long time periods and through multiple read cycles.

According to certain illustrative examples, the crossbar architecture (100) may be used to form a non-volatile memory array. Non-volatile memory has the characteristic of not losing its contents when no power is being supplied. Each of the programmable crosspoint devices (106) may be used to represent one or more bits of data. Although individual crossbar lines (108, 110) in FIG. 1 are shown with rectangular cross sections, crossbars may also have square, circular, elliptical, or more complex cross sections. The lines may also have many different widths, diameters, aspect ratios and/or eccentricities. The crossbars may be nanowires, sub-microscale wires, microscale wires, or wires with larger dimensions.

According to certain illustrative examples, the crossbar architecture (100) may be integrated into a Complimentary Metal-Oxide-Semiconductor (CMOS) circuit or other conventional computer circuitry. Each individual wire segment may be connected to the CMOS circuitry by a via (112). The via (112) may be embodied as an electrically conductive path through the various substrate materials used in manufacturing the crossbar architecture. This CMOS circuitry can provide additional functionality to the memristive device such as input/output functions, buffering, logic, configuration, or other functionality. Multiple crossbar arrays can be formed over the CMOS circuitry to create a multilayer circuit.

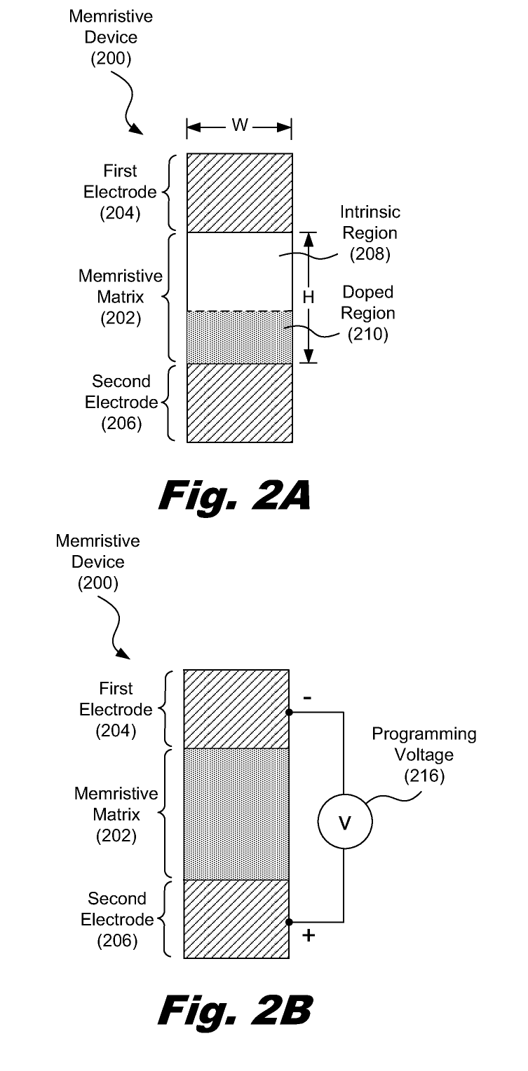

FIGS. 2A and 2B are diagrams showing an illustrative memristive device in different states. FIG. 2A illustrates one potential “as manufactured” state of the memristive device (200). The intrinsic region (208) has very few dopants and prevents electrical current from flowing between the two electrodes (204, 206). The doped region (210) is conductive and serves as a source of dopants which can be moved into the intrinsic region (208) to change the overall electrical conductivity of the memristive matrix (202). Consequently, in the “as manufactured” state of the memristive device illustrated in FIG. 2A, the memristive device (200) is a high resistive state.

The electrodes (204, 206) may be constructed from a variety of conducting materials, including but not limited to: metals, metal alloys, metal composite materials, nanostructured metal materials, or other suitable conducting materials.

The memristive matrix (202) has a height of “H” and a width of “W” as shown in FIG. 2A. For purposes of illustration, assume that the height “H” is 100 nanometers and the width “W” is approximately 50 nanometers. As discussed above, a relatively intense electric field can be generated across the thin film of memristive matrix by a relatively small voltage. For example, a dopant may require an electric field intensity of 100,000 volts per centimeter to move within the matrix. If the distance between two electrodes is 100 nanometers, a voltage bias of 1 Volt applied across the first electrode (204) and the second electrode (206) will produce an electric field intensity of 100,000 volts/centimeter through the memristive material (202). The application of a programming voltage above a certain threshold allows the dopants to be moved through the memristive matrix (202).

FIG. 2B is a diagram showing the memristive device (200) with a programming voltage (216) applied. The programming voltage (216) results in an electric field which facilitates not only the movement of dopants from the doped region (210) into the intrinsic region (208) but also the creation of some native dopants, such as oxygen vacancies, via an electro-reduction process in oxide memristive materials. The polarity and voltage difference which is applied across the memristive matrix (202) varies according to a variety of factors including, but not limited to: material properties, geometry, dopant species, temperature, and other factors. For example, when the ions are positively charged, the ions are repelled by positive voltage potentials and attracted to negative voltage potentials. For example, a positive voltage may be applied to the second electrode (206) and negative voltage may be applied to the first electrode (204).

According to one illustrative example, the initial application of a programming voltage (216) to the memristive device (200) is used to form the junction and define its characteristics. This initial programming voltage (216) may be higher than other applied voltages used for operational purposes. The initial programming voltage (216) may serve a number of functions which prepare the junction for further use. For example, the programming voltage (216) may result in the initial creation of additional mobile dopants or the migration of the mobile dopants into more active regions of the memristive matrix (202), which reduces the effective thickness of the memristive matrix (202) and causes an increased electric field with the same applied voltage. In addition, the electric field for dopant drift in the switching process is usually lower than that for dopant creation in the electroforming process. Consequently, lower programming voltages (216) can be subsequently used to move the dopants.

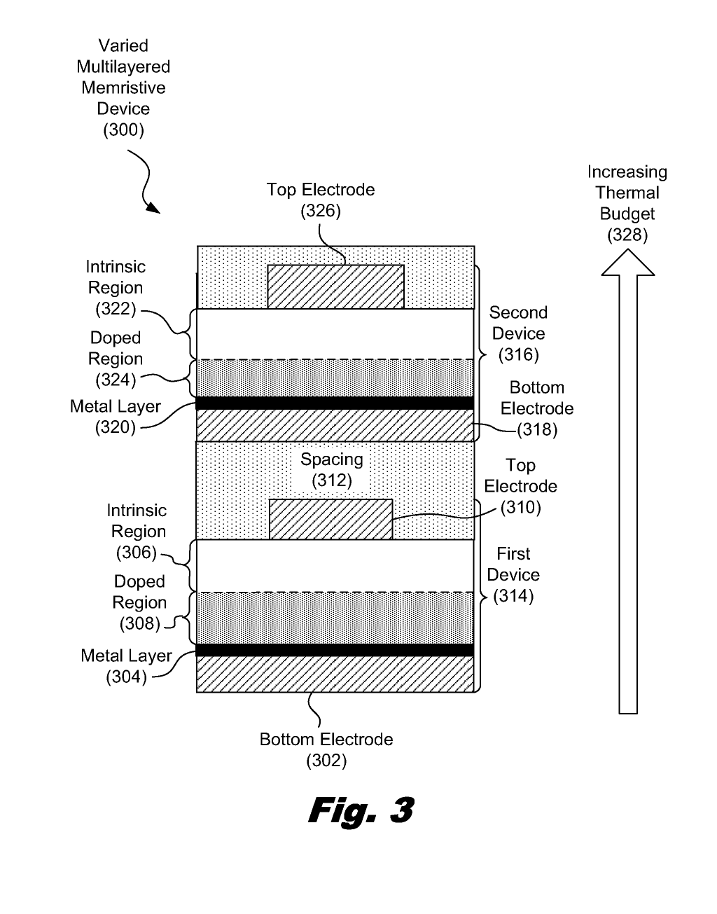

FIG. 3 is a diagram showing an illustrative varied multilayered memristive device (300). According to certain illustrative examples, the varied multilayered memristive device (300) includes a first memristive device (314) and a second memristive device (316) stacked on top of the first memristive device (314). A spacing element (312) composed of a dielectric material may be disposed between the two memristive devices (314, 316).

The first memristive device includes a bottom electrode (302), a metal layer (304), a doped region (308), an intrinsic region (306), and a top electrode (310). The first memristive device (314) may also include an interlayer dielectric used for isolation, intermediate structures, and materials that allow the device to be part of a layer as a repeatable unit of stacking. The electrodes (302, 310) may be made of a variety of conductive materials. In the case that the varied multilayered memristive device (300) is part of a crossbar array, the bottom electrode (302) may be a thin wire that runs perpendicular to the top electrode (310). As mentioned above a memristive device includes a doped region (308) adjacent to an intrinsic region (306). The doped region (308) acts as a source of dopants that drift into the intrinsic region (306) under application of certain electrical conditions. There is an associated thermal budget for the formation of the first memristive device (314).

In one example, the doped region (308) and intrinsic region (306) may be made of metal oxide materials. For example, the doped region (308) may be made of Ti₄O₇ and the intrinsic region (306) may be made of Ta₂O₅. In some cases, a thin metal layer (304) such as a titanium layer may be placed between the electrode (302) and the doped region (308). This metal layer (304) acts as an additional source of dopants.

The second memristive device (316) may also include a bottom electrode (318), a metal layer (320), a doped region (324) and an intrinsic region (322), and a top electrode (326), as well as interlayer dielectrics. Like with the first device (314), the bottom electrode (318) and the top electrode (326) of the second device (316) may be thin wires placed perpendicular to each other. The process of forming the second device on the first device (314) will also exhibit a thermal budget. This thermal budget will affect both the second device (316) and the first device (314) in addition to the thermal budget incurred during the formation of the first device (328). If the physical parameters of the second device (316) are substantially similar to the physical parameters of the first device (314), then the second device (316) will exhibit slightly different performance characteristics than the first device (314) due to the difference in thermal budget (328).

By varying certain physical parameters between the first device (314) and the second device (316), the desired performance characteristics may be adjusted to reach a desired goal. These performance characteristics may include, but are not limited to, current level, non-linearity, and operating voltage. For example, if it is desired that the two memristive devices exhibit substantially similar performance goals, then the physical parameters can be adjusted to do so when taking into account the thermal budget differences. Alternatively, if it is desired that the two memristive devices (314, 316) exhibit specific differences in performance to meet certain design goals, then the physical parameters may be varied accordingly while also taking into account the difference in thermal budget.

In the example of FIG. 3, the doped region (324) of the second device (316) has a reduced thickness compared to the doped region (308) of the first device (314). If there were no difference in thickness, then the cumulative thermal budget differences experienced between the formation processes for the first device (314) and the second device (316) may cause the dopants from the doped regions to diffuse into the intrinsic regions differently. However, if the thickness is varied as shown in FIG. 3, then the formation process can compensate for the diffusion differences resulting from thermal budget differences.

In some cases, other physical parameters between different devices (314, 316) may be used. For example, the metal layers (304, 320) may be varied between the first device (314) and the second device (316). Additionally or alternatively, the intrinsic regions (306, 322) may be varied between the first device (314) and the second device (316).

In some cases, different materials may be used for the different devices (314, 316). For example, the first device (314) may have an intrinsic region (306) made of Ta₂O₅ and a doped region (308) made of Ti₄O₇. Additionally, the second device (316) may have an intrinsic region made of TiO₂. Various differences in materials may compensate for thermal budget differences between the different stacked devices (314, 316). In some cases, the stacking sequence of the different regions may be varied.

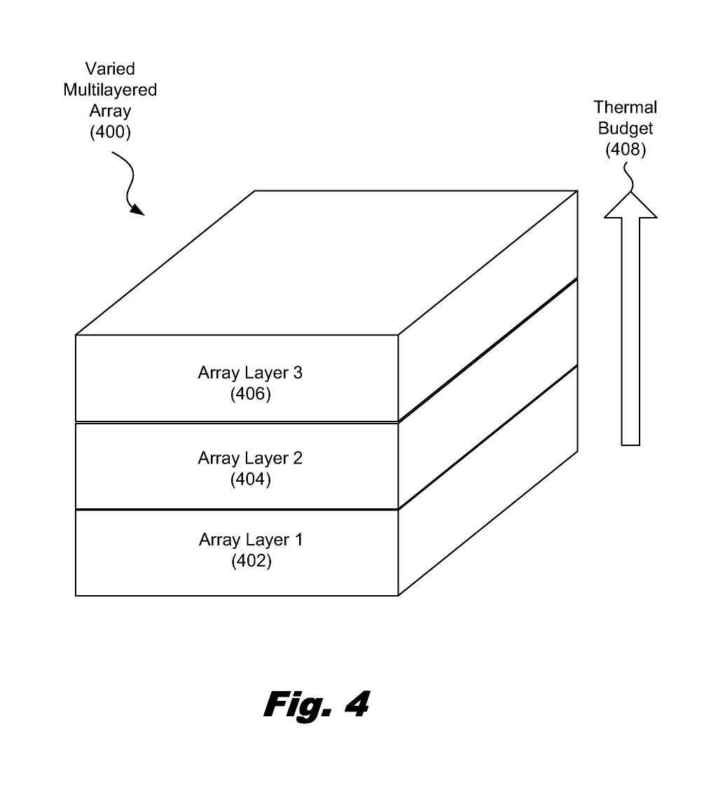

FIG. 4 is a diagram showing an illustrative varied multilayered memristive device array. According to certain illustrative examples, the varied multilayered array (400) includes three different array layers (402, 404, 406). These layers may be similar to the crossbar structure illustrated in FIG. 1. Each of the memristive elements on the same layer may be formed with similar physical parameters. However, these parameters may vary across different layers to account for the thermal budget (408). As mentioned above, these parameters may include the thickness of the doped regions, the thickness of the intrinsic regions, the thickness of a metallic layer, the type of material used to form the memristive matrix, and the stacking order used.

The varying of memristive devices across layers may be done despite the crossbar structure used. For example, some multilayered arrays may use crossbar arrays in which intersecting wires exist within the same layer. In some multilayered arrays, the crossbar architecture may have wires running within the same layer that perpendicularly intersect wires running vertically between the multiple layers.

Other memristive or memristive-like devices such as phase change memory and spin-torque transfer memory may be used for electronic storage. Such devices will also experience differences in thermal budget between different layers. Thus, the principles described herein regarding variation of physical parameters between different layers can be done to achieve uniform or specifically defined performance characteristics.

In addition to the thermal budget, other factors may affect the manufacturing process differently between different layers. For example, a fabrication process that is applied simultaneously to multiple layers of stacked memristive devices may have a cumulative effect on the layers. One example is etching a via that vertically intersects multiple layers of metallic electrodes. The process of etching such a via may cut into the metallic electrodes laterally. While the rate of such lateral etching is nearly consistent for each layer, the time exposed to the etching process differs between layers. Specifically, the upper layers are exposed to the etching longer than the lower layers. Thus, the higher a layer is within a stack, the more lateral etching an electrode within that layer will experience. Exposure to more lateral etching may cause the electrode to experience a higher series resistance.

To compensate for this variation in exposure to via etching, the electrodes can be made more resilient to the lateral component of etching by varying the composition of those electrodes per layer. Specifically, higher layers may be formed so that they are more resistant to the etching process. In some cases, the electrodes can be composed of two or more distinct metallic layers, each layer having a characteristic etch rate and resistivity. Thinner films generally experience less lateral etching than thicker films. Thus, the electrode layers in the higher stacking levels (further from the substrate), the component layer with a higher etch rate can be made thinner, while the lower level electrodes can contain a thicker layer of high etch rate material. This will result in relatively similar lateral etching between the multiple stacked layers. The specific thicknesses of the component films can be adjusted to create the desired distribution of series resistance among the stacked electrode layers. This desired distribution may be either uniform or intentionally varied.

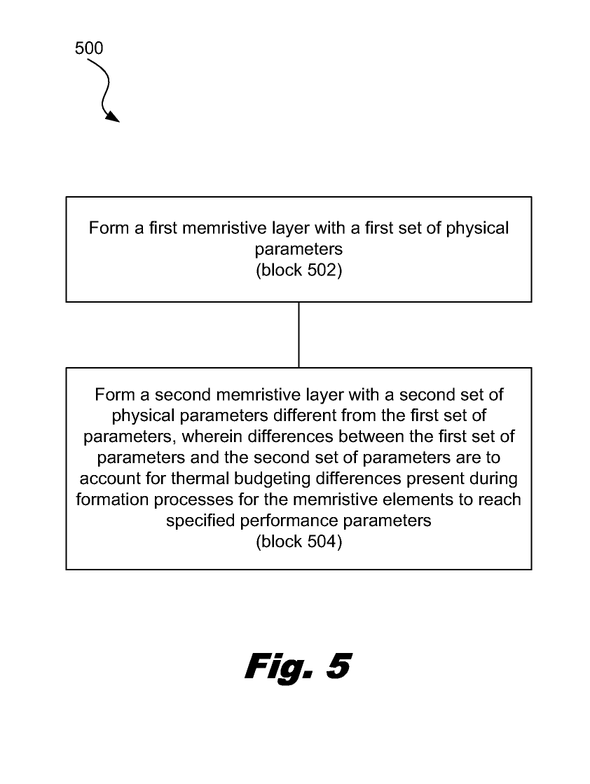

FIG. 5 is a flowchart showing an illustrative method for forming a varied multilayered memristive device. According to certain illustrative examples, the method includes forming (block 502) a first memristive layer with a first set of physical parameters, and forming (block 504) a second memristive layer with a second set of physical parameters different from the first set of parameters. The differences between the first set of parameters and the second set of parameters are to account for thermal budgeting differences present during formation processes for the memristive elements to reach specified performance parameters.

In conclusion, through use of methods and systems embodying principles described herein, multiple layers of memristive elements may exhibit specified performance characteristics despite thermal budget differences between the different layers. Specifically, by varying the physical parameters of the different layers while taking into account the thermal budget differences, specific performance goals may be accomplished according to design purposes.

The preceding description has been presented to illustrate and describe examples of the principles described. This description is not intended to be exhaustive or to limit these principles to any precise form disclosed. Many modifications and variations are possible in light of the above teaching.

What is claimed is:

1. A varied multilayer memristive device comprising:
a first memristive device stacked on a second memristive device;
wherein physical parameters of said second memristive device differ from physical parameters of said first memristive device to account for thermal budgeting differences present during formation processes for said memristive devices and to reach specified performance parameters.

2. The device of claim 1, wherein said physical parameters comprise at least one of: thickness of a highly doped region, thickness of an intrinsic region, thickness of a metal layer, types of materials, and stacking order.

3. The device of claim 1, wherein a highly doped region of said second memristive device is of a smaller thickness than a doped region of said first memristive device.

4. The device of claim 1, in which the variation of said physical parameters of said first memristive device and said physical parameters of said second memristive device are varied to achieve similar performance between said first memristive device and said second memristive device within a predefined tolerance level.

5. The device of claim 1, in which the variation of said physical parameters of said first memristive device and said physical parameters of said second memristive device are varied to achieve specified differences in performance between said first memristive device and said second memristive device within a predefined tolerance level.

6. The device of claim 1, wherein said performance parameters comprise at least one of: current level, non-linearity, and operating voltage.

7. The device of claim 1, further comprising additional memristive devices stacked on said second memristive device, physical parameters of each of said additional devices differing from physical parameters of other devices to account for thermal budgeting differences present during formation processes for said memristive devices and to reach specified performance parameters.

8. The device of claim 1, wherein a metal layer of said first memristive device is varied from a metal layer of said second memristive device to compensate for etching differences between formation of said memristive devices.

9. A method for creating a varied multilayer memristive device, the method comprising:
forming a first memristive layer with a first set of physical parameters; and
forming a second memristive layer with a second set of physical parameters different from said first set of parameters;
wherein differences between said first set of parameters and said second set of parameters are to account for thermal budgeting differences present during formation processes for said memristive devices to reach specified performance parameters.

10. The method of claim 9, wherein said sets of parameters comprise at least one of: thickness of a highly doped region, thickness of an intrinsic region, thickness of a metal layer, types of materials, and stacking order.

11. The method of claim 9, wherein a highly doped region of said second memristive device is of a smaller thickness than a doped region of said first memristive device.

12. The method of claim 9, in which differences between said first set of parameters and said second set of parameters are to achieve similar performance between said first memristive device and said second memristive device within a predefined tolerance level.

13. The method of claim 9, in which differences between said first set of parameters and said second set of parameters are to achieve specified differences in performance between said first memristive device and said second memristive device within a predefined tolerance level.

14. The method of claim 9, wherein said performance parameters comprise at least one of: current level, non-linearity, and operating voltage.

15. A multilayered memristive crossbar structure comprising:
a first layer comprising an array of memristive devices having a first set of physical parameters; and
a second layer comprising a second array of memristive devices having a second set of physical parameters;
wherein differences between said first set of parameters and said second set of parameters are to account for thermal budgeting differences present during formation processes for said memristive devices to reach specified performance parameters.
